(19) United States
(12) Patent Application Publication
(10) Pub. No.: US 2020/0207559 A1
(43) Pub. Date: Jul. 2, 2020

(54) DUST-FREE SYSTEM AND METHOD OF MANUFACTURING PANEL

(71) Applicant: INT TECH CO., LTD., Hsinchu County (TW)

(72) Inventors: Ruei Ken KAO, New Taipei City (TW); Cheng-Hsin CHEN, Hsinchu County (TW)

(21) Appl. No.: 16/235,737

(22) Filed: Dec. 28, 2018

(51) Int. Cl. B65G 69/18; B65G 69/20

(52) U.S. Cl. CPC B65G 69/181; C23C 14/22; B65G 69/20

(57) ABSTRACT

A method for manufacturing a panel and a dust-free system for manufacturing a panel are provided. The method includes several operations. A first operation on a substrate in a first machine station is performed. A second operation on the substrate in a second machine station is performed. The substrate is transferred between the first machine station and the second machine station, wherein the substrate is transferred in a mini-environment by a panel carrier.

### TECHNICAL FIELD

The present disclosure is related to a dust-free system and a method for manufacturing a panel using the same.

### BACKGROUND

Display panels have important applications in consumer electronics, entertainment, military and other fields. A typical manufacturing process of a panel includes numerous steps. For example, lithography is a crucial step that greatly affects the performance of the panel. As pixel pitches of the panel are gradually decreased for providing greater resolution, small particles, including even those with a scale of micrometers, in the manufacturing environment can contaminate the panel substrate and lead to defects of the panel. Product yield is therefore decreased by exposure of the panel substrate to particles of micrometer scale.

### SUMMARY

From an aspect, the present disclosure provides a method for manufacturing a panel. The method includes several steps. A first operation on a substrate in a first machine station is performed, and a second operation on the substrate in a second machine station is then performed. The substrate is transferred between the first machine station and the second machine station, wherein the substrate is transferred in a mini-environment by a panel carrier.

In an embodiment of the present disclosure, the first and second operations comprise at least one of: a coating operation, a deposition operation, an exposure operation, a developing operation, a packaging operation and an inspection.

In an embodiment of the present disclosure, the panel carrier comprises at least one of a machine arm, crane system, a panel cart and a conveyor system.

In an embodiment of the present disclosure, the step of transferring the substrate includes: filling a cart chamber of the panel carrier with a gas, wherein the gas is circulated into and out of the cart chamber; interconnecting the cart chamber of the panel cart and a buffer chamber of the first machine station to form a space filled with the gas; transferring the substrate from the buffer chamber into the cart chamber; separating the panel cart and the first machine station; and transferring the substrate from the mini-environment of the cart chamber to the second machine station.

In an embodiment of the present disclosure, the step of transferring the substrate includes: forming the mini-environment in the panel carrier; connecting the panel carrier to the first machine station; loading the substrate into a buffer chamber of the first machine station from the mini-environment of the panel carrier; and disconnecting the panel carrier and the first machine station.

In an embodiment of the present disclosure, the method further includes: filling a gas into the mini-environment, wherein the gas is selected from at least one of nitrogen and inert gases.

In an embodiment of the present disclosure, the method further includes: filtering the gas to be filled into the mini-environment.

In an embodiment of the present disclosure, the mini-environment conforms to ISO class 3 environment, having a maximum of 8 particles per cubic meter that are 1 micrometer or larger; a maximum of 35 particles per cubic meter that are 0.5 micrometers or larger; a maximum of 102 particles per cubic meter that are 0.3 micrometers or larger; a maximum of 237 particles per cubic meter that are 0.2 micrometers or larger; and a maximum of 1000 particles per cubic meter that are 0.1 micrometers or larger.

From another aspect, the present disclosure provides a dust-free system for panel manufacturing. The dust-free system includes: a cabin, a plurality of machine stations, an air pump and a filter. The cabin defines a mini-environment. The plurality of machine stations is for performing different manufacturing operations, and each of the machine stations has a load port connecting the mini-environment of the cabin. The air pump is to pump a gas into and out of the mini-environment. The filter is at a gas entrance to the mini-environment to filter the gas in the mini-environment.

In an embodiment of the present disclosure, the load port of each of the machine stations is inside the cabin.

In an embodiment of the present disclosure, the dust-free system further includes: a plurality of transfer chambers, in the mini-environment inside the cabin, wherein each of the transfer chambers is connected to the load port of one of the machine stations.

In an embodiment of the present disclosure, the dust-free system further includes: a panel carrier, transferring a substrate between the machine stations in the mini-environment.

In an embodiment of the present disclosure, the panel carrier includes at least one of a machine arm, a crane system, a panel cart and a conveyor system.

In an embodiment of the present disclosure, a pressure inside the panel carrier is substantially the same as a chamber pressure of one of the machine stations, and is greater than a pressure of the mini-environment.

In an embodiment of the present disclosure, the dust-free system further includes: an air knife, producing airflow at an entrance of the mini-environment of the cabin.

From another aspect, the present disclosure provides a dust-free system for manufacturing a panel. The dust-free system includes: a plurality of machine stations and a panel carrier. The plurality of machine stations is for performing different manufacturing operations, and each of the machine stations has a load port. The panel carrier transfers a substrate between the machine stations in a mini-environment, wherein the panel carrier includes a cart chamber, an air circulation system and a filter. The cart chamber defines the mini-environment on the panel carrier. The air circulation system is to pump gas into and out of the mini-environment. The filter is to filter the gas of the mini-environment.

In an embodiment of the present disclosure, the panel carrier further includes: a first port, connected to the air circulation system to pump the gas into the cart chamber; a second port, connected to the air circulation system to pump the gas out of the cart chamber; and a fan, to facilitate air circulation in the mini-environment and filtration of the gas.

In an embodiment of the present disclosure, the panel carrier further includes: a loading interface, connected to the chamber of the panel carrier, providing access of the substrate into the mini-environment of the cart chamber.

In an embodiment of the present disclosure, the panel carrier further includes: an air knife, producing airflow at the loading interface of the panel carrier.

In an embodiment of the present disclosure, the filter is an ultra-low penetration air filter.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a flowchart showing various steps of a method for manufacturing a panel in accordance with some embodiments of the present disclosure.

FIGS. 2, 3, 4 and 5 are schematic diagrams illustrating a dust-free system for manufacturing a panel in accordance with different embodiments of the present disclosure.

FIG. 6 is a cross-sectional view of a part of the dust-free system shown in FIG. 5.

FIG. 7 is a schematic diagram illustrating a dust-free system for manufacturing a panel in accordance with some embodiments of the present disclosure.

FIGS. 8A, 8B and 8C are schematic diagrams illustrating a panel carrier as viewed from different direction in accordance with some embodiments of the present disclosure.

FIGS. 9A, 9B and 9C are schematic diagrams illustrating a panel carrier as viewed from different direction in accordance with some embodiments of the present disclosure.

FIG. 10 is a schematic diagram illustrating a panel carrier in accordance with some embodiments of the present disclosure.

FIG. 11A is a schematic diagram illustrating a part of a panel carrier in accordance with some embodiments of the present disclosure.

FIG. 11B is a schematic diagram illustrating air circulation of the panel carrier shown in FIG. 11A in accordance with some embodiments of the present disclosure.

FIGS. 12A, 12B and 12C are schematic diagrams of one or more operations of a panel carrier connecting to a machine station in accordance with some embodiments of the present disclosure.

FIGS. 13 and 14 are schematic diagrams illustrating a dust-free system for manufacturing a panel in accordance with different embodiments of the present disclosure.

FIG. 15 shows schematic diagrams of one or more operations of a panel carrier transferring a substrate from a machine station in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

In one or more embodiments of the present disclosure, a dust-free system and a method for manufacturing a panel thereof are provided. The dust-free system includes machine stations and a panel carrier for transferring a substrate of the panel in a mini-environment conforming to an ISO class 1, 2 or 3 environment. INC) class 4 and 5 environments allow for larger and more particles present in the clean room, which may be appropriate for less-critical manufacturing processes. However, as pixel pitches of the panel are gradually decreased for providing greater resolution, ISO class 1, 2 or 3 environments are required to transfer the substrate between the machine stations throughout the manufacturing process. In particular, lithographic operations (including developing and exposure operations) are critical to a panel having a pixel pitch of about 5 micrometers, or a smallest distance between pixels of about 1 micrometer.

The ISO class 5 environment may have a maximum of 29 particles per cubic meter that are 5 micrometers or larger; a maximum of 832 particles per cubic meter that are 1 micrometer or larger; a maximum of 3,520 particles per cubic meter that are 0.5 micrometers or larger; a maximum of 10,200 particles per cubic meter that are 0.3 micrometers or larger; a maximum of 23,700 particles per cubic meter that are 0.2 micrometers or larger; and a maximum of 100,000 particles per cubic meter that are 0.1 micrometers or larger. The ISO class 4 environment may have 0 particles per cubic meter that are 5 micrometers or larger; a maximum of 83 particles per cubic meter that are 1 micrometer or larger; a maximum of 352 particles per cubic meter that are 0.5 micrometers or larger; a maximum of 1,020 particles per cubic meter that are 0.3 micrometers or larger; a maximum of 2,370 particles per cubic meter that are 0.2 micrometers or larger; and a maximum of 10,000 particles per cubic meter that are 0.1 micrometers or larger.

The ISO class 3 environment may have 0 particles per cubic meter that are 5 micrometers or larger; a maximum of 8 particles per cubic meter that are 1 micrometer or larger; a maximum of 35 particles per cubic meter that are 0.5 micrometers or larger; a maximum of 102 particles per cubic meter that are 0.3 micrometers or larger; a maximum of 237 particles per cubic meter that are 0.2 micrometers or larger; and a maximum of 1000 particles per cubic meter that are 0.1 micrometers or larger. The ISO class 2 environment may have 0 particles per cubic meter that are 1 micrometer or larger; a maximum of 4 particles per cubic meter that are 0.5 micrometers or larger; a maximum of 10 particles per cubic meter that are 0.3 micrometers or larger; a maximum of 24 particles per cubic meter that are 0.2 micrometers or larger; and a maximum of 100 particles per cubic meter that are 0.1 micrometers or larger. The ISO class 1 environment have 0 particles per cubic meter that are 0.3 micrometers or larger; a maximum of 2 particles per cubic meter that are 0.2 micrometers or larger; and a maximum of 10 particles per cubic meter that are 0.1 micrometers or larger.

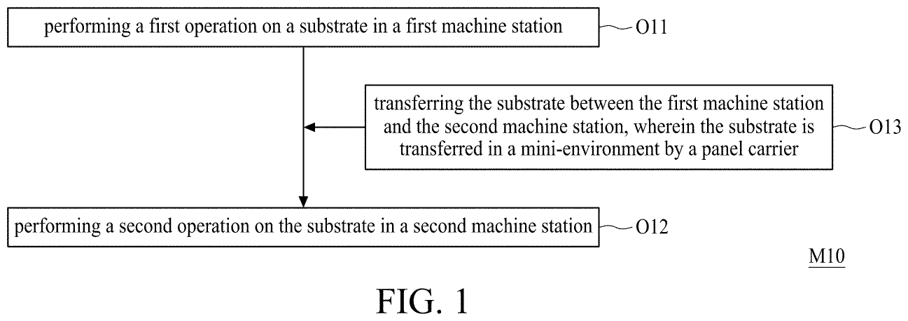

FIG. 1 is a flow chart illustrating a method M10 for manufacturing a panel according to various aspects of one or more embodiments of the present disclosure. The method M10 includes several operations and performed in a single semiconductor manufacturing system. The method M10 includes: (O11) performing a first operation on a substrate in a first machine station; (O12) performing a second operation on the substrate in a second machine station; and (O13) transferring the substrate between the first machine station and the second machine station, wherein the substrate is transferred in a mini-environment by a panel carrier. It should be noted that the steps of the method M10 may be rearranged or otherwise modified within the scope of the various aspects.

In order to further illustrate concepts of the present disclosure, various embodiments are provided below. However, it is not intended to limit the present disclosure to specific embodiments. In addition, elements, conditions or parameters illustrated in different embodiments can be combined or modified to have different combinations of embodiments as long as the elements, parameters or conditions used are not conflicted. For ease of illustration, reference numerals with similar or same functions and properties are repeatedly used in different embodiments and figures, but it does not intend to limit the present disclosure into specific embodiments.

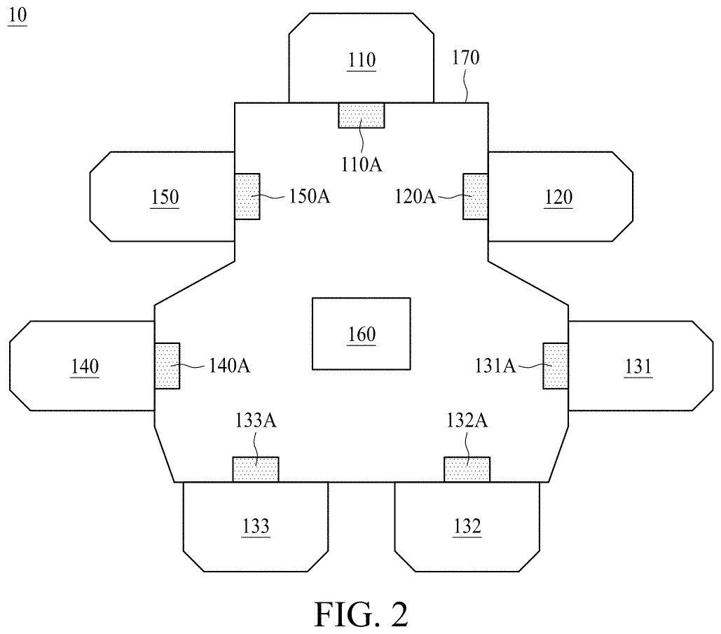

FIG. 2 is a schematic diagram illustrating a dust-free system 10 for performing the method M10 for manufacturing a panel in accordance with some embodiments of the present disclosure. The dust-free system 10 includes a plurality of machine stations 110, 120, 131, 132, 133, 140 and 150, and a panel carrier 160. In some embodiments, the machine station 110 is for performing a coating operation, a developing operation and a photoresist removal operation on a substrate of the panel. In some embodiments, the machine station 120 is for performing an exposure operation on the substrate of the panel. In some embodiments, the machine station 131 is for performing deposition of red pixels on the substrate of the panel. In some embodiments, the machine station 132 is for performing deposition of blue pixels on the substrate of the panel. In some embodiments, the deposition includes evaporation. In some embodiments, the machine station 133 is for performing deposition of green pixels on the substrate of the panel. In some embodiments, the machine station 140 is for performing a packaging operation on the substrate of the panel. In some embodiments, the machine station 150 is for performing an inspection of the panel.

Different machine stations for performing different operations of the manufacturing process can be included in the dust-free system provided by the present disclosure. A number and types of the machine stations are not limited herein. In some embodiments, all machine stations necessary to manufacture the panel from a raw substrate (e.g., a blank wafer or polysilicon substrate) are included in the dust-free system of the present disclosure.

The dust-free system 10 also includes a panel carrier 160 to transfer the panel between the machine stations 110, 120, 131, 132, 133, 140 and 150 in a mini-environment, wherein the mini-environment conforms to an ISO class 1, 2 or 3 environment. In some embodiments, the panel carrier 160 includes at least one of a machine arm, a crane system, a panel cart and a conveyor system.

In order to provide the mini-environment for the substrate transferring, in some embodiments, the dust-free system 10 includes a cabin 170 to define the mini-environment, and the panel carrier 160 is arranged inside the cabin 170. In some embodiments, the entire space defined by the cabin 107 is the mini-environment conforming to the ISO class 1, 2 or 3 environment. As shown in FIG. 2, each of the machine stations 110, 120, 131, 132, 133, 140 and 150 has a load port 110A, 120A, 131A, 132A, 133A, 140A or 150A respectively, and the load ports 110A, 120A, 131A, 132A, 133A, 140A and 150A are in the cabin 170 while the remaining portions of the machine stations 110, 120, 131, 132, 133, 140 and 150 are outside the cabin 170. In some embodiments, at least the load ports of the machine stations for performing lithographic operations (including developing operations and exposure operations) are inside the cabin 170. In some embodiments, the entire machine stations 110, 120, 131, 132, 133, 140 and 150 are inside the cabin 170. However, only the load ports 110A, 120A, 131A, 132A, 133A, 140A or 150A are necessary to be inside the mini-environment to reduce cost for the cleanroom construction and functioning. In some embodiments, the panel carrier 160 is connected to one of the load ports 110A, 120A, 131A, 132A, 133A, 140A and 150A while loading and unloading the substrate onto or from one of the corresponding machine stations 110, 120, 131, 132, 133, 140 and 150. In some embodiments, the mini-environment is a vacuum environment, a nitrogen environment, or an environment filled with one of the inert gases.

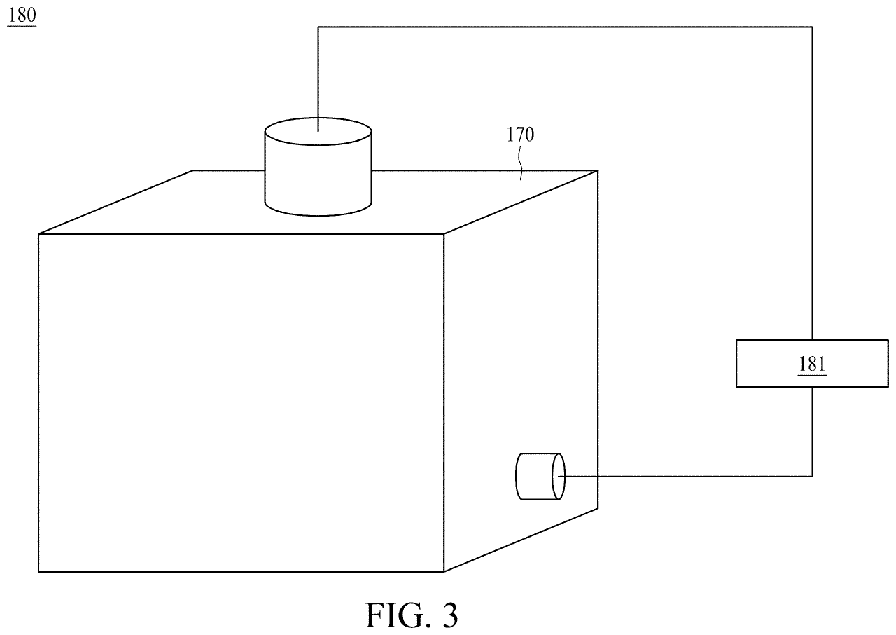

In some embodiments, the dust-free system 10 further includes an air circulation system 180 connected to the cabin 170 to circulate the gas or pump the gas into and out of the cabin 170. As shown in FIG. 3, in accordance with some embodiments, the air circulation system 180 includes an air pump 181 to pump one or more gases into or out of the mini-environment of the cabin 170. The air pump 181 can be arranged inside or outside the cabin 170, and is not limited herein. The air pump 181 may connect to the mini-environment in the cabin 170 through pipes. The air pump 181 functions to circulate the gas in the cabin 170, pump the gas out of the cabin 170 to produce a vacuum environment, or pump nitrogen or inert gases into the cabin 170 to produce a desired mini-environment. In some embodiments, circulation of a gas (e.g., nitrogen gas) provides a benefit of controlling humidity and oxygen percentage in the mini-environment, and incurs very little effect on or contamination to the substrate during transferring.

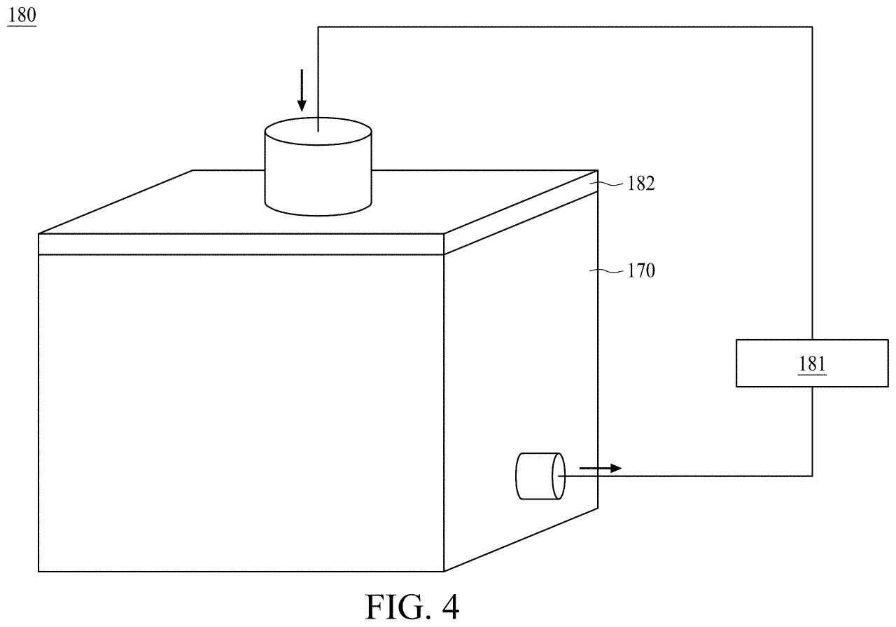

In some embodiments, the dust-free system 10 further includes a filter 182, as shown in FIG. 4, disposed in the path of the air circulation, which filters the gas before the gas enters the mini-environment. In some embodiments, the filter 182 is arranged inside the air circulation system 180. The filter 182 functions to filter the gas pumped into the mini-environment of the cabin 170. In some embodiments, the filter 182 is at an entrance of the mini-environment where the gas is pumped in. In some embodiments, the filter 182 is a layer configuration at a top of the cabin 170 covering on top of the entire mini-environment. In some embodiments, the filter 182 includes at least one of an ultra-low penetration air filter (ULPA) and a high-efficiency particulate air (HEPA) filter to ensure that the mini-environment is maintained in a condition conforming to the ISO class 1, 2 or 3 environment. In some embodiments, the filter 182 has a pore size in a range of 0.1 to 1 micrometers.

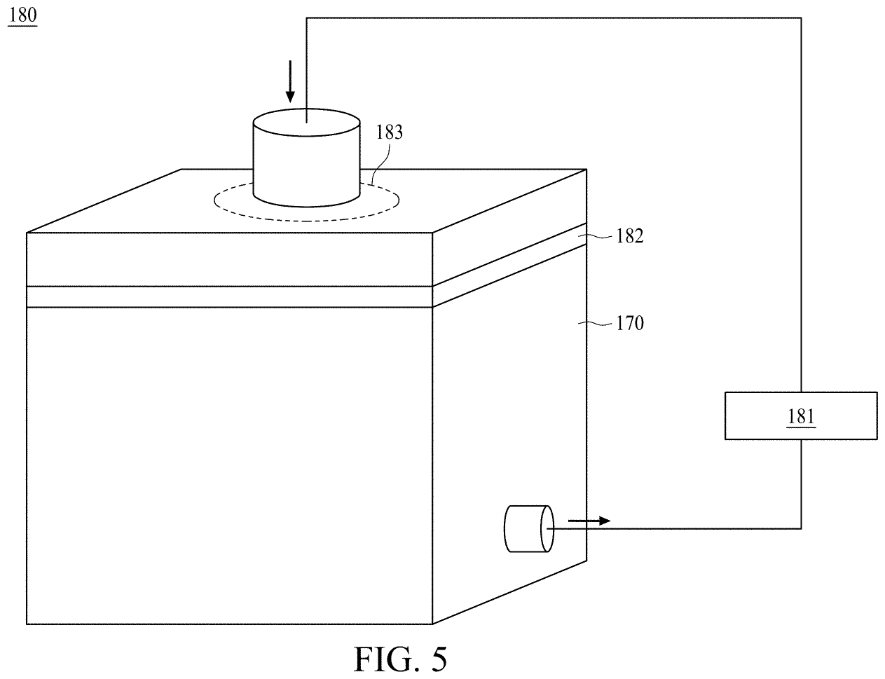

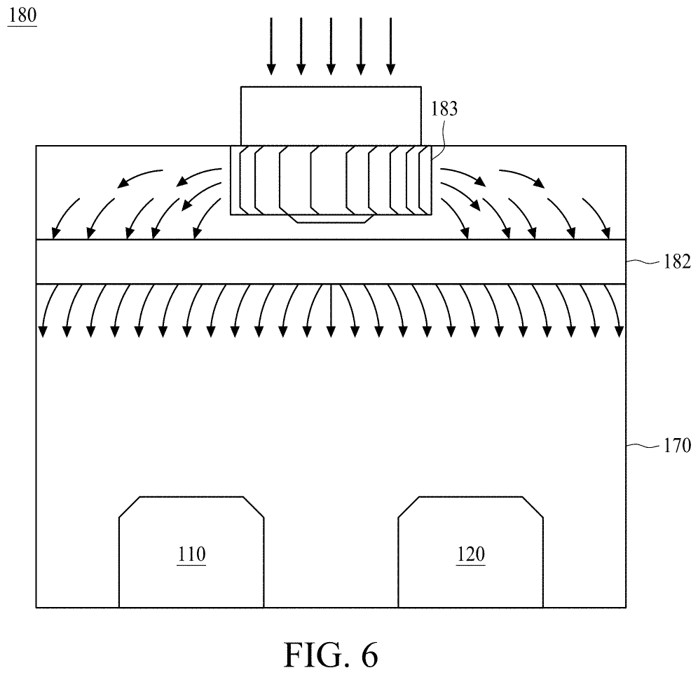

In some embodiments, the dust-free system 10 further includes a fan 183 as shown in FIGS. 5 and 6 to facilitate air circulation in the mini-environment as well as into and out of the mini-environment. The fan 183 can also facilitate filtration of the gas of the mini-environment. FIG. 5 is a schematic diagram illustrating the dust-free system 10 in accordance with some embodiments of the present disclosure. FIG. 6 is a cross-sectional view of a part of the dust-free system 10 shown in FIG. 5 to illustrate the arrangement of the fan 183, the filter 182, the air circulation system 180 and the cabin 170. In some embodiments, the fan 182 is inside the cabin 170 and outside the mini-environment, and is at a side of the filter 183 opposite to the machine stations 110, 120, 131, 132, 133, 140 and 150 (only the machine stations 110 and 120 are shown in FIG. 6). In some embodiments, the fan 183 and the filter 182 are parts of a fan filter unit (FFU).

In some embodiments, the dust-free system 10 further includes an air knife at an entrance of the mini-environment (not shown) or the interface between the mini-environment and the outer environment. The air knife can produce airflow at an entrance of the mini-environment. The air knife functions to compress a gas and release the gas in a direction to produce airflow. The airflow can remove particles from objects or people entering the mini-environment, and reduces chances of contamination of the mini-environment in the cabin 170. An environment with well-circulated air and a stable airflow control system is advantageous to the manufacturing process. In addition, a good exhaust system of the air circulation system can provide a safe environment in case of chemical leakage.

A processing sequence of the conventional manufacturing process is limited by the environment. For instance, in a conventional manufacturing process, the depositions of pixels of all three colors are designed to be performed in sequence in order to reduce possibility of contamination. However, as the load ports of all the machine stations 110, 120, 131, 132, 133, 140 and 150 are inside the mini-environment, orders of operations of the manufacturing process of the panel can be adjusted. Formation of different colors of pixels can be individually performed, and inspections for pixels of one color can be respectively performed to ensure product yield of pixels of a color before formation of pixels of another color. Flexibility of adjusting process parameters and conditions is increased. An assurance check can be more comprehensive, and improvement and adjustment can be conducted. For instance, the coating operation, the exposure operation, the developing operation, the inspection, the deposition of green pixels, and the photoresist removal operation are sequentially performed to form green pixels. Similar sequences are performed to form red pixels and blue pixels. Subsequently, the packaging operation is performed to form the panel.

Following the same concept, similar results can be achieved by different implementation of the mini-environment as illustrated in different embodiments in the following description.

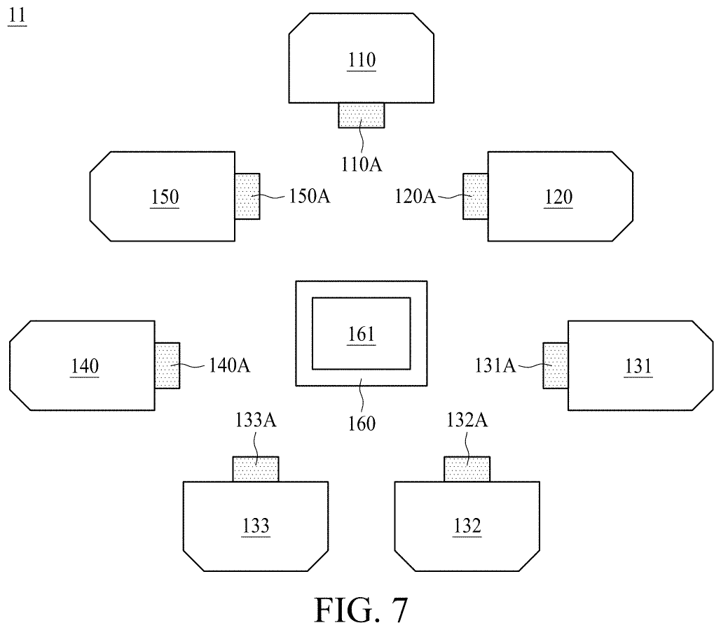

FIG. 7 is a schematic diagram illustrating a dust-free system 11 for performing the method M10 for manufacturing a panel in accordance with some embodiments of the present disclosure. The dust-free system 11 includes a plurality of machine stations 110, 120, 131, 132, 133, 140 and 150, and a panel carrier 160. In the embodiments shown in FIG. 7, there is no cabin 170, and a mini-environment is carried out in a cart chamber 161 of the panel carrier 160. A substrate is transferred between the machine stations 110, 120, 131, 132, 133, 140 and 150 in the mini-environment in the panel carrier 160.

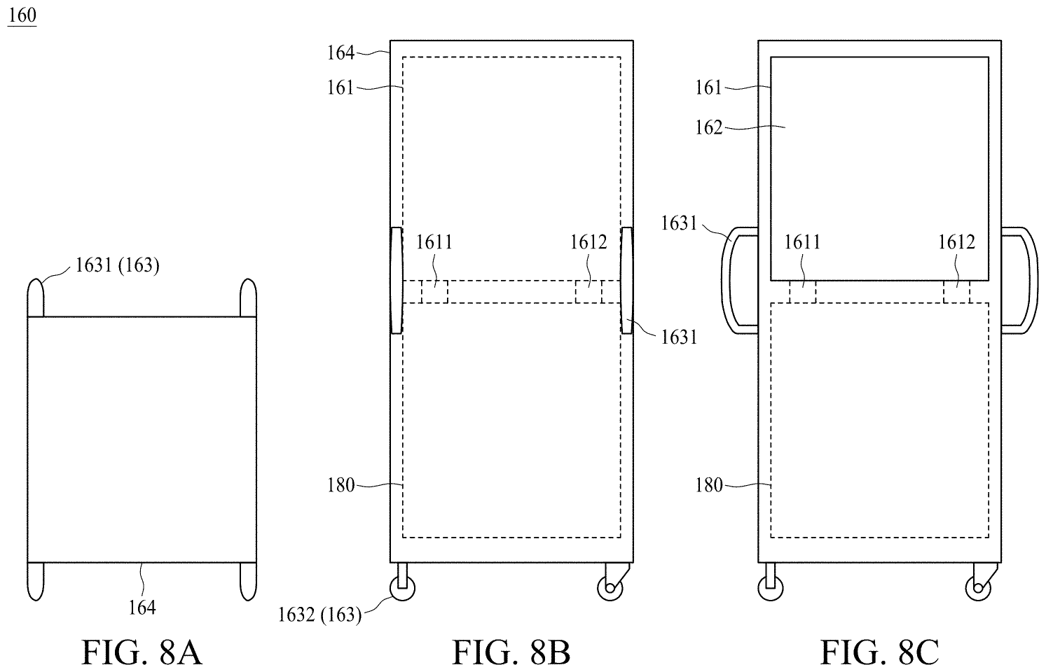

FIGS. 8A, 8B and 8C are schematic diagrams illustrating the panel carrier 160 as viewed from different directions, wherein FIG. 8A is a top view, FIG. 8B is a front view, and FIG. 8C is a side view of the panel carrier 160 in accordance with some embodiments of the present disclosure. The panel carrier 160 includes the cart chamber 161 and a loading interface 162. The loading interface 162 is connected to the cart chamber 161 providing access of the substrate into or out of the cart chamber 161. In order to produce the mini-environment in the cart chamber 161, an air circulation system 180 is installed on the panel carrier 160 and connected to the cart chamber 161 through a first port 1611 and a second port 1612. The first port 1611 of the panel carrier 160 interconnects the air circulation system 160 and the cart chamber 161 to pump the gas into the cart chamber 161. The second port 1612 of the panel carrier 160 interconnects the air circulation system 160 and the cart chamber 161 to pump (or exhaust) the gas out of the cart chamber 161. The air circulation system 180 is similar to the embodiments shown in FIG. 3, and repeated description is omitted herein.

In some embodiments, the panel carrier 160 further includes an auto-navigation system (not shown) to control movement of the panel carrier 160 between the machine stations 110, 120, 131, 132, 133, 140 and 150 by a default sequence. The route of the panel carrier 160 can be programmed and installed in the auto-navigation system on the panel carrier 160 or manually controlled remotely through a control interface on the panel carrier 160 or from outside the mini-environment. In some embodiments, the panel carrier 160 includes an outer case 164 to accommodate the cart chamber 161 and the air circulation system 180. In some embodiments, the panel carrier 160 further includes a mobile supplement 163. In some embodiments, the mobile supplement 163 includes a handle 1631 on the outer case 164 of the panel carrier 160 for manual control of movement of the panel carrier 160. In some embodiments, the mobile supplement 163 includes a wheel 1632 at the bottom of the outer case 164 of the panel carrier 160 for ease of movement.

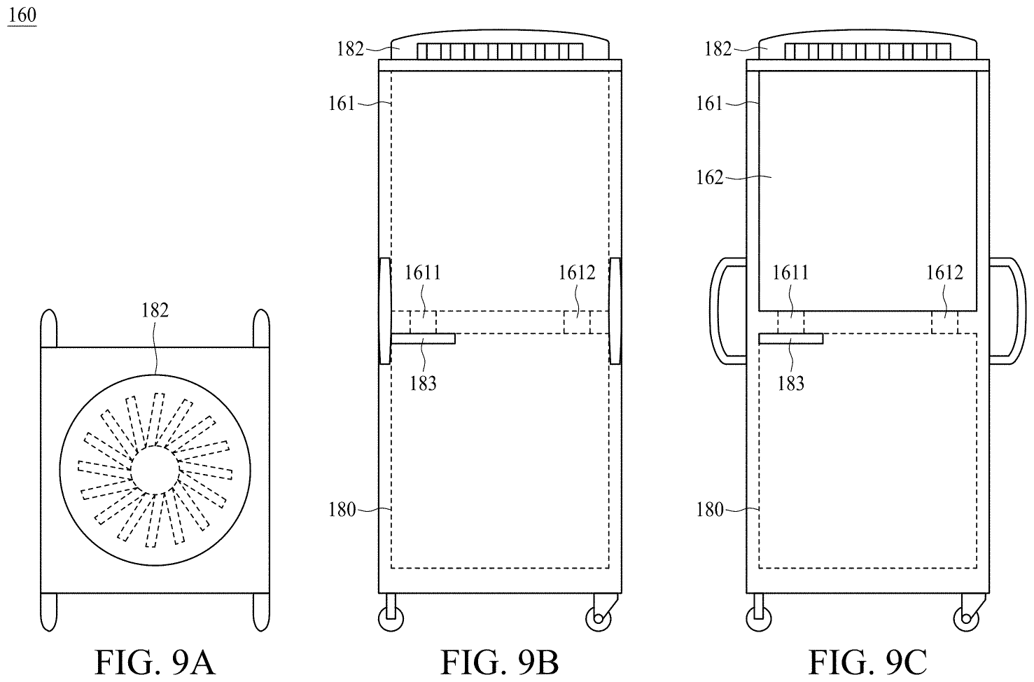

FIGS. 9A, 9B and 9C are schematic diagrams illustrating the panel carrier 160 as viewed from different directions, wherein FIG. 9A is a top view, FIG. 9B is a front view, and FIG. 9C is a side view of the panel carrier 160 in accordance with some embodiments of the present disclosure. In some embodiments, a filter 183 is arranged on the panel carrier 160 in the air circulation system 180 where the gas is pumped into the cart chamber 161. In some embodiments, the filter 183 is disposed on the panel carrier 160 between the air circulation system 180 and the mini-environment of the chamber 160, and at an entrance of the mini-environment for gas injection. However, a position of the filter 183 is not limited herein as long as the same results of filtration can be achieved. In some embodiments, the filter 182 includes at least one of an ultra-low penetration air filter (ULPA) and a high-efficiency particulate air (HEPA) filter to ensure that the mini-environment is maintained in a condition conforming to the ISO class 1, 2 or 3. In some embodiments, the filter 182 has a pore size in a range of 0.1 to 1 micrometers.

In some embodiments as shown in FIGS. 9A, 9B and 9C, the panel carrier 160 further includes a fan 182 to facilitate air circulation in the mini-environment and filtration of the gas. It should be noted that arrangements of the pipes/pathway on the cart chamber 161 for gas intake and exhaust shown in the figures are for illustration only, and are not intended to limit the present disclosure. In some embodiments, the fan 182 is electrically connected to the air circulation system 180 and is operated together with the air circulation system 180. In some embodiments, the fan 182 is electrically isolated from the air circulation system 180.

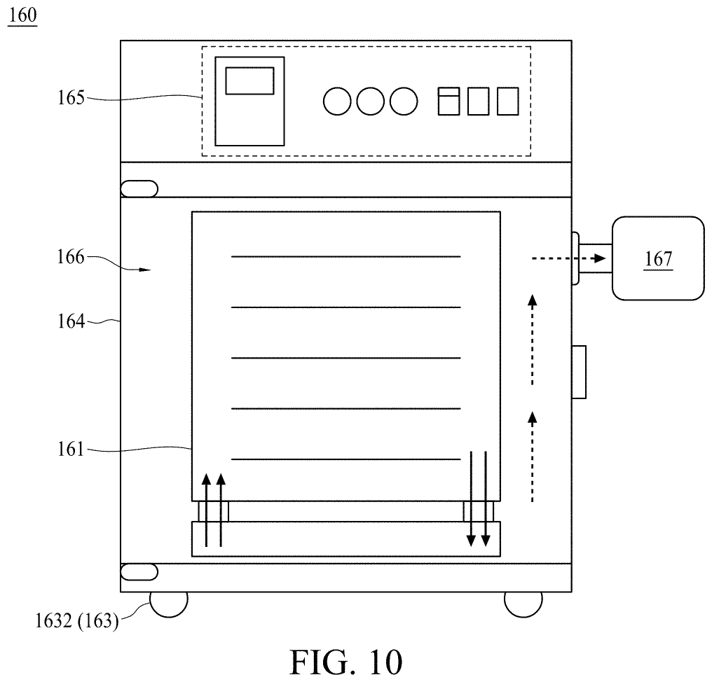

FIG. 10 is a schematic diagram illustrating the panel carrier 160 in accordance with some embodiments of the present disclosure. In the embodiments shown in FIG. 10, the panel carrier 160 is similar to the panel carriers 160 shown in FIGS. 8A, 89, 8C, 9A, 99 and 9C, except the panel carrier 160 in FIG. 10 has a control interface 165 on the panel carrier 160, and the cart chamber 161 proximal to a center of the panel carrier 160. The control interface 165 is over the cart chamber 161 for manual control of movement of the panel carrier 160 and for monitoring conditions of the mini-environment in the cart chamber 161. In some embodiments, a vacuum environment is formed between the outer case 164 and the cart chamber 161. In addition, the gas in the mini-environment in the cart chamber 161 can be easily pumped into the vacuum environment 166 and then pumped out of the panel carrier 160 by, for example, a vacuum pump 167.

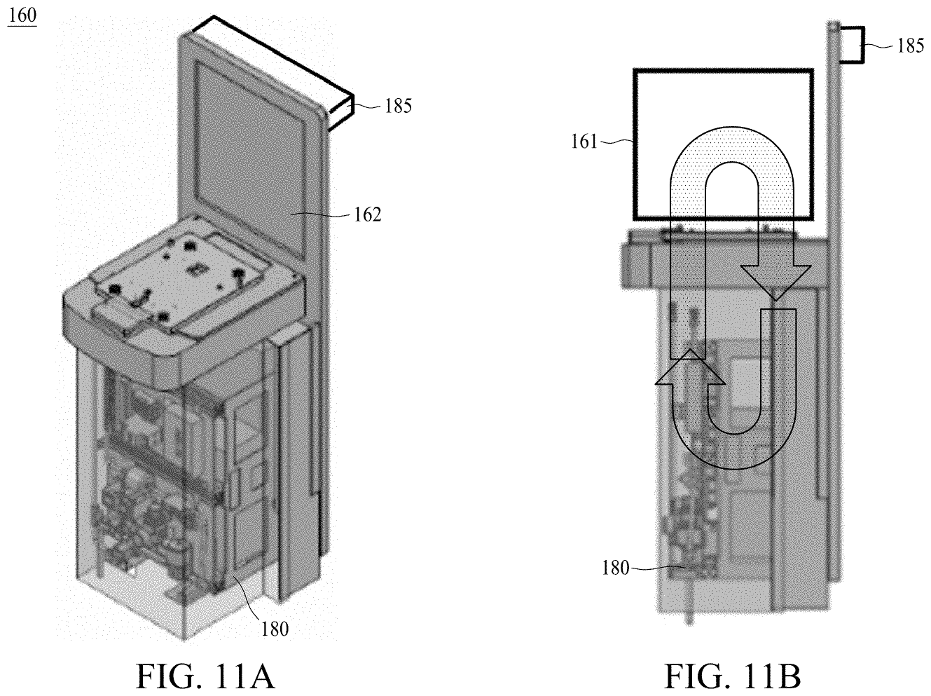

FIGS. 11A and 11B are schematic diagrams illustrating the panel carrier 160 in accordance with some embodiments of the present disclosure, wherein FIG. 11A is a perspective view without the cart chamber 161, and FIG. 119 is a side view illustrating airflow with arrows during the air circulation. In some embodiments, the dust-free system 10 further includes an air knife 185 at the loading interface 162 to produce airflow at an entrance of the mini-environment of the chamber 160. The air knife 185 functions to compress a gas and force the gas out in a direction to produce airflow. The airflow can remove particles in the environment and reduce chances of contamination while loading/unloading the substrate.

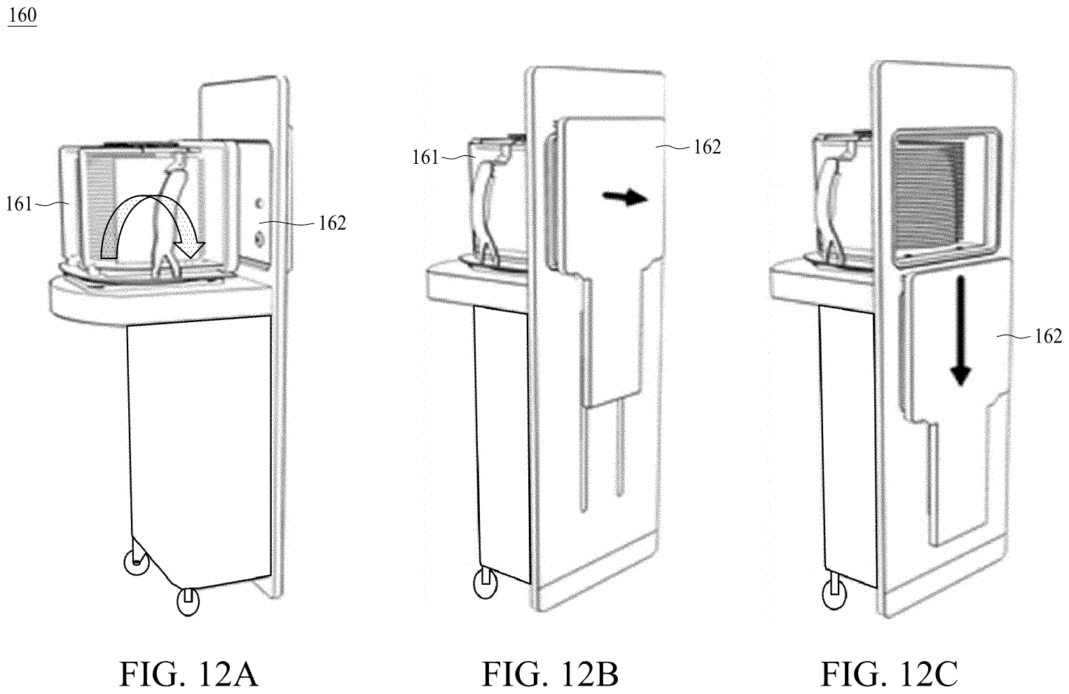

FIGS. 12A, 12B, 12C are schematic diagrams illustrating the panel carrier 160 in accordance with some embodiments of the present disclosure while loading/unloading the substrate. FIG. 12A shows the loading interface 162 closed while transferring the substrate, and the cart chamber 161 is filled with nitrogen circulated by the air circulation system 180. FIGS. 12B and 12C show the loading interface 162 being opened after the panel carrier is securely connected to the load port. The loading interface 162 is designed to be opened in two steps such that the loading interface 162 is slid to right and then down to completely open the cart chamber 161 for loading/unloading the substrate. After the loading interface 162 is opened, the mini-environment in the cart chamber 161 is interconnected with a buffer chamber of the load port. As the processing is very delicate, especially the developing operation and the exposure operation, the buffer chamber of the load port is designed to be an ISO class 1, 2 or 3 environment. The mini-environment formed by the cart chamber 161 and the buffer chamber also conforms to the ISO class 1, 2 or 3 environment. In some embodiments, the mini-environment of the cart chamber 161 is adjusted to be similar to or the same as the mini-environment of the buffer chamber of the load port. Therefore, the substrate is loaded, unloaded and transferred in the mini-environment conforming to the ISO class 1, 2 or 3 environment throughout the manufacturing process.

In some embodiments, the panel carrier 160 is made of materials with surface treatment to reduce static electrical effect. In some embodiments, the outer case 164 is made of 304 stainless steel or 316L stainless steel. In some embodiment, the loading interface 161 is transparent. In some embodiments, a material of the loading interface 161 is similar to or the same as the material of a sliding door of a wet bench. In some embodiments, the panel carrier 160 includes a fan filter unit (FFU), wherein the fan 183 and filter 182 are parts of the FFU. In some embodiments, the panel carrier 160 includes a battery and a charging system designed for continuous performance for at least one hour. In some embodiments, the panel carrier 160 can perform continually for a period in a range of 1 to 4 hours.

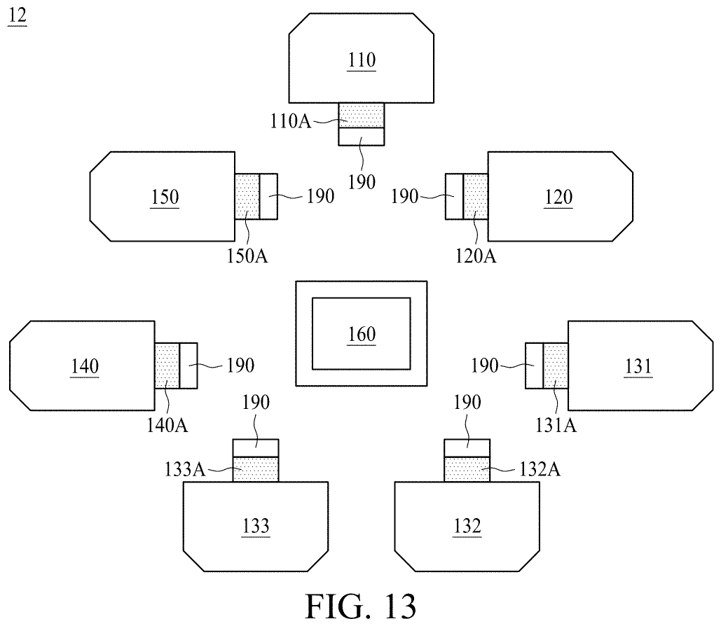

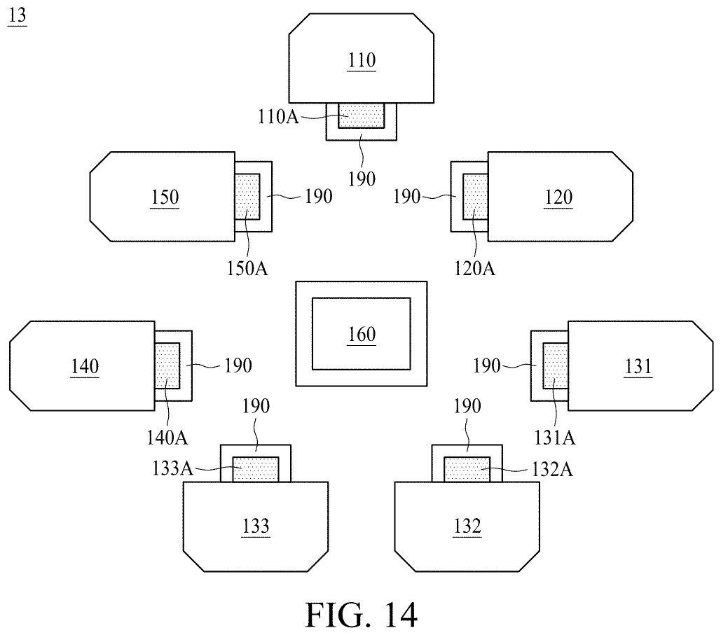

FIGS. 13 and 14 are schematic diagrams respectively illustrating a dust-free system 12 and a dust-free system 13 for performing the method M10 for manufacturing a panel in accordance with some embodiments of the present disclosure. The dust-free system 12 is similar to the dust-free system 10, except the mini-environment of the dust-free system 12 is defined by a plurality of transfer chambers 190, rather than the cabin 170. The transfer chambers 190 connect to the load ports 110A, 120A, 131A, 132A, 133A, 140A and 150A respectively. More specifically, the transfer chamber 190 is securely connected to or encapsulates the gate of the buffer chamber of each of the load ports 110A, 120A, 131A, 132A, 133A, 140A and 150A. In some embodiments, the transfer chamber 190 hermetically encapsulates each of the load ports 110A, 120A, 131A, 132A, 133A, 140A and 150A, as shown in FIG. 14. The mini-environment is produced and defined by the transfer chamber 190. While the substrate is transferring, the panel carrier 160 is inside the transfer chamber 190 for loading/unloading the substrate. The buffer chamber of the load port is opened, and the mini-environment is defined by the connected buffer chamber and transfer chamber 190. Therefore, the substrate is loaded onto or unloaded from the panel carrier 160 inside the mini-environment and contamination during substrate transferring between the machine stations 110, 120, 131, 132, 133, 140 and 150 can be prevented. In the embodiments of the dust-free system 12, the panel carrier 160 can be optionally connected to the load portion of the machine station in a secure manner.

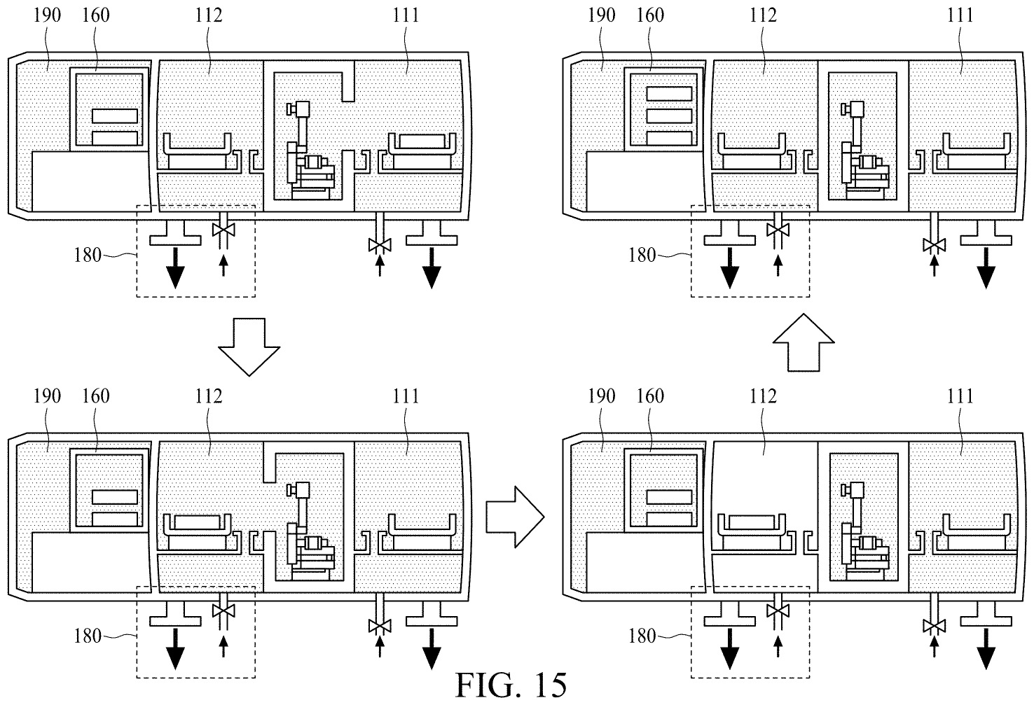

FIG. 15 shows schematic diagrams illustrating the process of transferring the substrate onto the panel carrier 160. Using the machine station 110 as an example, the machine station 110 includes a process chamber 111 and a buffer chamber 112. In some embodiments, the buffer chamber 112 is at the load port 110A, and is connected to an air circulation system 180 to pump a gas (for example, nitrogen gas) into and out of the process chamber 111. The panel carrier 160 is moved into the transfer chamber 190. The gate of the buffer chamber 112 is then opened, and the transfer chamber 190 is interconnected with the buffer chamber 112. Nitrogen gas is pumped into the transfer chamber 190 through the buffer chamber 112 to form a mini-environment. The buffer chamber 112 is closed in order to be isolated from the transfer chamber 190 after a homogeneous state of the mini-environment is reached in the transfer chamber 190 and the buffer chamber 112. The substrate is transferred from the process chamber 111 to the buffer chamber 112 by, e.g. a machine arm. The gas in the buffer chamber 112 is then pumped out to form a vacuum environment to remove possible particles. Subsequently, the gas is refilled into the buffer chamber 112, and the buffer chamber 112 and the transfer chamber 190 are again interconnected. In some embodiments, the amount of gas pumped into the buffer chamber 112 and the air pressure in the buffer chamber 112 are controlled to be the same as those in the transfer chamber 190 to avoid airflow while opening the buffer chamber 112 to connect to the transfer chamber 190. The buffer chamber 112 is closed in order to disconnect from the transfer chamber 190 after the substrate is transferred onto the chamber of the panel carrier 160. Subsequently, the transfer chamber 190 is opened, and the panel carrier 160 is moved out of the transfer chamber 190 to another machine station. The transferring process of a substrate from the panel carrier 160 onto a load port of a machine station is similar to the transferring process as shown in FIG. 15, and detailed illustration is not repeated herein.

In some embodiments without the air circulation system 180 on the panel carrier, the cart chamber 161 remains open during the process shown in FIG. 15, and is closed after transferring the substrate onto the panel carrier 160 and before opening the transfer chamber 190 to move the panel carrier 160 to another machine station. In some embodiments with the air circulation system 180 on the panel carrier 160, the cart chamber 161 is opened only while loading or unloading the substrate to or from the cart chamber 161. In such embodiments, a pressure of the cart chamber 161 inside the panel carrier 160 is greater than a pressure of the mini-environment of the transfer chamber 190. In some embodiments with the panel carrier 160 directly and securely connecting to the buffer chamber 112, a pressure of the cart chamber 161 inside the panel carrier 160 is substantially the same as a chamber pressure of the buffer chamber 112 of the machine station 110, and is greater than a pressure of the mini-environment of the transfer chamber 190 while loading and unloading the substrate. In some embodiments, a pressure of the mini-environment (or the transfer chamber 190) is greater than a pressure of the outer environment outside the mini-environment (or the transfer chamber 190). Different pressures in different environments can produce an air flow while connecting two different environments, and can prevent particles from moving from a low-pressure environment into a high-pressure environment.

In some embodiments, the transfer chamber 190 is connected to an individual air circulation system 180. In some embodiments, the exhaust and refilling operations can be performed on the transfer chamber 190, the buffer chamber 112 or both, to remove any particles after every closing of the transfer chamber 190 or the buffer chamber 112. A number of times or an interval of performing the exhaust and refilling operations during the loading and unloading is not limited herein. A cycle of the exhaust and refilling operations can reduce particle contamination.

In some embodiments, the transfer chamber 190 is connected to the air circulation system 180, the filter 182 and/or the fan 183, as in the embodiments shown in FIGS. 2 to 6. In addition, one or more of the cabins 170 as shown in FIG. 2, the panel carriers 160 with the mini-environment as shown in FIGS. 8 to 12, or the transfer chamber 190 as shown in FIGS. 13 and 15 can be used to combine different embodiments to achieve better results. For instance, the cabin 170 and the panel carrier 160 shown in FIG. 9 are used. In such embodiments, a first mini-environment conforming to the ISO class 3 environment is defined by the cabin 170, and a second mini-environment conforming to the ISO class 1 environment is defined by the panel carrier 160. Double security is provided to the manufacturing process of the panel in case the panel carrier 160 is not connected to the load port 110A, 120A, 131A, 132A, 133A, 140A or 150A correctly, and the substrate is transferred in the ISO class 1 environment even when the first mini-environment is not an ISO class 1 environment. In some embodiments, a pressure of the cart chamber 161 inside the panel carrier 160 is substantially the same as a chamber pressure of the buffer chamber of the machine station, and is greater than a pressure of the mini-environment in the cabin 170 while the substrate is being loaded and unloaded. In addition, the pressure of the mini-environment in the cabin 170 is greater than a pressure of the outer environment outside the cabin 170.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a panel, comprising:
performing a first operation on a substrate in a first machine station;
performing a second operation on the substrate in a second machine station; and
transferring the substrate between the first machine station and the second machine station, wherein the substrate is transferred in a mini-environment by a panel carrier.

2. The method of claim 1, wherein the first and second operations comprise at least one of: a coating operation, a deposition operation, an exposure operation, a developing operation, a packaging operation and an inspection.

3. The method of claim 1, wherein the panel carrier comprises at least one of a machine arm, crane system, a panel cart and a conveyor system.

4. The method of claim 1, wherein transferring the substrate comprises:
filling a cart chamber of the panel carrier with a gas, wherein the gas is circulated into and out of the cart chamber;
interconnecting the cart chamber of the panel cart and a buffer chamber of the first machine station to form a space filled with the gas;
transferring the substrate from the buffer chamber into the cart chamber;
separating the panel cart and the first machine station; and
transferring the substrate from the mini-environment of the cart chamber to the second machine station.

5. The method of claim 1, wherein transferring the substrate comprises:
forming the mini-environment in the panel carrier;
connecting the panel carrier to the first machine station;
loading the substrate into a buffer chamber of the first machine station from the mini-environment of the panel carrier; and
disconnecting the panel carrier and the first machine station.

6. The method of claim 1, further comprising:
filling a gas into the mini-environment, wherein the gas is selected from at least one of nitrogen and inert gases.

7. The method of claim 6, further comprising:
filtering the gas to be filled into the mini-environment through a filter having a pore size in a range of 0.1 to 1 micrometer.

8. The method of claim 1, wherein the mini-environment conforms to ISO class 3 environment, having a maximum of 8 particles per cubic meter that are 1 micrometer or larger; a maximum of 35 particles per cubic meter that are 0.5 micrometers or larger; a maximum of 102 particles per cubic meter that are 0.3 micrometers or larger; a maximum of 237 particles per cubic meter that are 0.2 micrometers or larger; and a maximum of 1000 particles per cubic meter that are 0.1 micrometers or larger.

9. A dust-free system for panel manufacturing, comprising:
a cabin, defining a mini-environment;
a plurality of machine stations, performing different manufacturing operations, each of the machine stations having a load port connecting the mini-environment of the cabin;
an air pump, to pump a gas into and out of the mini-environment; and
a filter, being at a gas entrance to the mini-environment to filter the gas in the mini-environment.

10. The dust-free system of claim 11, wherein the load port of each of the machine stations is inside the cabin.

11. The dust-free system of claim 11, further comprising:
a plurality of transfer chambers, in the mini-environment inside the cabin, wherein each of the transfer chambers is connected to the load port of one of the machine stations.

12. The dust-free system of claim 11, further comprising:
a panel carrier, transferring a substrate between the machine stations in the mini-environment.

13. The dust-free system of claim 12, wherein the panel carrier includes at least one of a machine arm, a crane system, a panel cart and a conveyor system.

14. The dust-free system of claim 13, wherein a pressure inside the panel carrier is substantially the same as a chamber pressure of one of the machine stations, and is greater than a pressure of the mini-environment.

15. The dust-free system of claim 11, further comprising:
an air knife, producing airflow at an entrance of the mini-environment of the cabin.

16. A dust-free system for manufacturing a panel, comprising:
a plurality of machine stations, performing different manufacturing operations, each of the machine stations having a load port; and
a panel carrier, transferring a substrate between the machine stations in a mini-environment, the panel carrier comprising:
a cart chamber, defining the mini-environment; and
an air circulation system to pump gas into and out of the mini-environment; and
a filter, filtering the gas of the mini-environment.

17. The dust-free system of claim 16, wherein the panel carrier further comprises:
a first port, connected to the air circulation system to pump the gas into the cart chamber;
a second port, connected to the air circulation system to pump the gas out of the cart chamber; and
a fan, to facilitate air circulation in the mini-environment and filtration of the gas.

18. The dust-free system of claim 16, wherein the panel carrier further comprises:
a loading interface, connected to the chamber of the panel carrier, providing access of the substrate into the mini-environment of the cart chamber.

19. The dust-free system of claim 18, wherein the panel carrier further comprises:
an air knife, producing airflow at the loading interface of the panel carrier.

20. The dust-free system of claim 17, wherein the filter is an ultra-low penetration air filter.
